(19) United States
(12) Patent Application Publication
(10) Pub. No.: US 2008/0079442 A1
(43) Pub. Date: Apr. 3, 2008

(54) Quantum tunneling biometric identification methods and apparatuses

(76) Inventor: Joshua Posamentier, Oakland, CA (US)

Correspondence Address: SCHUBERT, OSTERRIEDER & NICKELSON, PLLC;c/o Intellevate, P.O. BOX 52050, MINNEAPOLIS, MN, 55402, US

(21) Appl. No.: 11/513,967

(22) Filed: Aug. 31, 2006

(51) Int. Cl. G01R 27/02

(52) U.S. Cl. 324/605

(57) ABSTRACT

Methods, apparatuses, and systems to identify biometric characteristics of people and things are disclosed. Embodiments generally comprise sensors that contain arrays of pads or electrodes. In various embodiments, current or voltage sources generate quantum tunneling currents from the arrays of pads to biometric components using select elements as ground return paths. In many embodiments, currents sources apply varying magnitudes of voltages to individual pads in the arrays to create the quantum tunneling currents. In these embodiments, the sensors or electronics coupled to the sensors create voltage profiles of the biometric components by measuring the individual magnitudes of voltages. In some embodiments the individual magnitudes of voltages may be acquired via accumulation state machines and stored in random access memory. In many embodiments, the profiles are compared with other voltage profiles to identify people. Some embodiments involve granting access to computing services when the profile matches a known profile.

### FIELD

The present invention is in the field of biometric identification. More particularly, the present invention relates to methods, apparatuses, and systems to identify biometric characteristics of people and things.

### BACKGROUND

Fingerprinting is one of the oldest and most reliable methods of identifying individuals. Generally, fingerprint identification methods involve creating and comparing impressions or images of ridge formations, or patterns, located on the fingertips and thumb-tips on the hands of people. Since no two people have the same pattern of loops, whorls, or arches, using fingerprints to differentiate one individual from the next has proven to be a highly reliable method of identifying persons via biometric data.

It comes as no surprise, then, that fingerprinting and other methods of biometric identification have migrated into the realm of computer and electronic device security. As we have increased our usage of computers and other electronic devices over the years, especially in the arena of mobile computing devices, the need to restrict access to many of those devices has caused problems. For instance, it is not uncommon for a person having to remember multiple log-in identifications (IDs), multiple passwords, numerous personal identification number (PIN) codes, and countless online profiles. Various types of biometric sensors, coupled with secure log-in routines, have helped people eliminate the need to memorize innumerable passwords. A person may scan an image of his or her fingerprint using a fingerprint scanner and generally gain access to computing services that would otherwise require them to log in with a user ID and password. Unfortunately, the fingerprint scanners and other biometric sensors in use today have numerous drawbacks.

The majority of fingerprint scanners today employ optical scanning techniques. A major problem with optical fingerprint scanners is cost. Simply put, optical fingerprint scanners have high packaging costs and suffer from problems related to quality control. Additionally, even when the optical scanners are manufactured properly, they still suffer from other optical-related problems, such as dirt and contrast issues due to different skin types. The second-most common technology for biometric scanners is capacitive sensor technology. Capacitive sensors generally employ a grid of electrodes. When a person presses his or her fingertip against the sensor containing the electrodes, the surface of the finger serves as a type of capacitor plate. The various ridges and valleys of the fingerprint have varying degrees of distance from the capacitive plates in the sensor. The sensor measures minute quantities of capacitance across the area of the sensor to develop a capacitive profile that represents the fingerprint image. While capacitive sensors tend to overcome some of the problems related to optical sensors, the capacitive sensors still have drawbacks. For instance, capacitive sensors tend to require large quantities of amplifiers to generate voltages for the sensor electrodes, which result in large and complex sensor circuitry. Additionally, both optical and capacitive sensors may often be defeated by replicas of fingerprint images or patterns.

### BRIEF DESCRIPTION OF THE DRAWINGS

Aspects of the invention will become apparent upon reading the following detailed description and upon reference to the accompanying drawings in which like references may indicate similar elements:

FIG. 1 depicts a system to identify individuals by using biometric information;

FIG. 2A depicts an embodiment of a biometric sensor apparatus;

FIG. 2B illustrates how an embodiment of a biometric sensor may generate tunneling currents and measure the voltage magnitudes required to generate the tunneling currents;

FIG. 3 depicts an alternative embodiment of a biometric apparatus;

FIG. 4A depicts one embodiment of a biometric sensor implemented as a chip;

FIG. 4B-4D illustrate various implementations of pad arrays; and

FIG. 5 illustrates a method for identifying an individual and granting access to a computing service, based upon biometric information obtained from quantum tunneling currents.

### DETAILED DESCRIPTION OF EMBODIMENTS

The following is a detailed description of embodiments of the invention depicted in the accompanying drawings. The embodiments are in such detail as to clearly communicate the invention. However, the amount of detail offered is not intended to limit the anticipated variations of embodiments; but on the contrary, the intention is to cover all modifications, equivalents, and alternatives falling within the spirit and scope of the present invention as defined by the appended claims. The detailed descriptions below are designed to make such embodiments obvious to a person of ordinary skill in the art.

Generally speaking, methods, apparatuses, and systems to identify biometric characteristics of people and things are contemplated. Embodiments generally comprise sensors that contain arrays of electrodes or pads. In these embodiments, current sources generate quantum tunneling currents from the arrays of pads to biological components. In many method embodiments, the current sources apply varying magnitudes of voltages to the pads in the arrays to create the quantum tunneling currents. In these embodiments, the sensors or electronics coupled to the sensors create voltage profiles of the biometric components by measuring the individual magnitudes of voltages. In some embodiments the individual magnitudes of voltages may be gathered or collected via accumulation state machines and stored in random access memory devices. In many embodiments, the profiles are compared with other voltage profiles to identify people. Some embodiments involve granting access to computing services when the measured profile matches a known profile.

The apparatus embodiments described herein generally have either current or voltage sources that generate quantum tunneling currents to flow from an array of pads, through dielectric mediums, to biometric components. Some apparatuses comprise ground elements coupled to the current sources which provide return paths for the quantum tunneling currents. Some apparatuses have a layer of insulating material coupled to the array of pads. Some apparatus embodiments may have one or more multiplexers coupled to the voltage modules to allow the voltage modules to measure the voltages of the pads. In various embodiments, the voltage module may comprise one or more analog-to-digital converters. In many embodiments, the apparatus embodiments may be used to sense arrangements of ridges and valleys of a human hand, such as a fingerprint.

System embodiments generally comprise arrays of current sources to generate quantum tunneling currents which flow through dielectric mediums, from the arrays of pads, to biometric components. The embodiments also generally comprise voltage modules to measure the magnitudes of voltages of the arrays of pads, as well as power supplies coupled to the arrays of pads to generate the quantum tunneling currents. Various system embodiments may have layers of insulating materials coupled to the arrays of pads. Other system embodiments may have ground elements coupled to the arrays of pads to provide return paths for the quantum tunneling currents. Alternative system embodiments may comprise processors which compare the magnitudes of voltages with stored magnitudes of voltages to identify individuals.

While portions of the following detailed discussion describe embodiments to identify people via biometric characteristics, persons of ordinary skill in the art will recognize that alternative embodiments may involve identifying biometric characteristics of other types of animals, such as livestock, domestic pets, or wild animals. Additionally, while some portions of the discussion describe using current sources to generate the quantum tunneling currents, some embodiments may generate the quantum tunneling currents using voltage sources. In other words, electronic circuits designed to operate with current sources may sometimes perform the same functions as those electronic circuits designed with substituted voltage sources. Consequently, current sources and voltage sources may sometimes be substituted or interchanged.

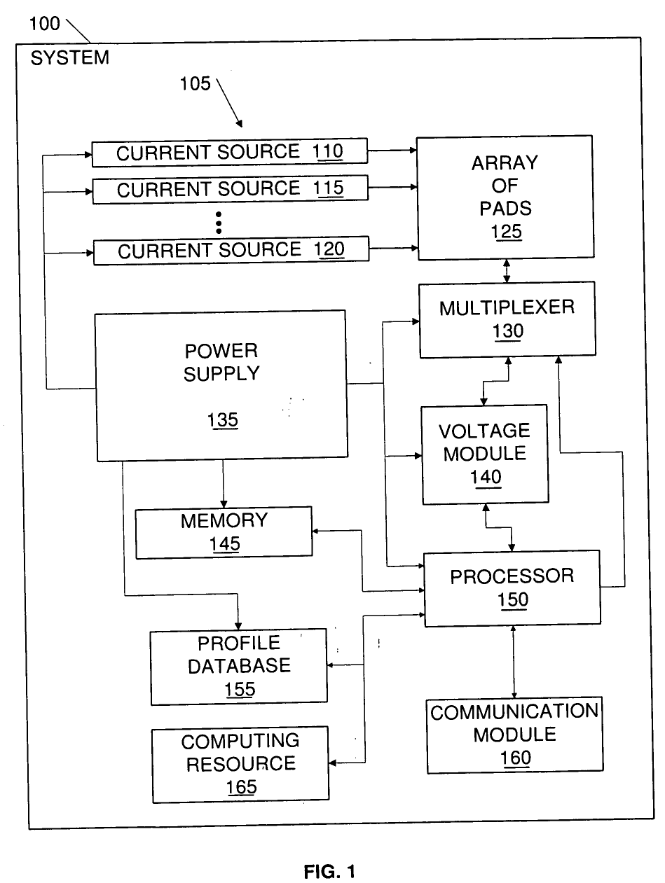

Turning now to the drawings, FIG. 1 depicts a system 100 that may identify people and things via biometric characteristics. In some embodiments system 100 may comprise a computer system, such as a notebook or palmtop computer. In other embodiments system 100 may comprise a mobile computing system used to identify people are things. For example, system 100 may comprise a mobile or portable apparatus used to scan and identify livestock or domestic pets. In even further embodiments, system 100 may comprise an automatic teller machine or a secure access system for a building or a gated community.

As depicted in FIG. 1, system 100 has an array of current sources 105 comprised of current source 110, current source 115, and current source 120. The array of current sources 105 may be driven by a power supply 135. Power supply 135 may also supply operating power to other elements in system 100, such as multiplexer 130, voltage module 140, and processor 150. The array of current sources 105 may generate quantum tunneling currents from sensor electrodes or pads in an array of pads 125. The array of current sources 105 may generate these quantum tunneling currents whenever a person or animal introduces a biometric component in close proximity to the array of pads 125. For example, the array of current sources 105 may generate these quantum tunneling currents whenever person places his or her hand on a sensor containing the array of pads 125. In some embodiments the sensor containing the array of current sources 105 may be relatively small, such as half an inch by half an inch. In other embodiments the sensor of may be relatively large, such as six inches by eight inches, which may be large enough to accommodate a palm of a person.

Once the array of pads 125 generates the quantum tunneling currents, voltage module 140 may measure the direct current (DC) voltage potential of each of the individual pads in the array of pads 125 via multiplexer 130 and processor 150. In other words, processor 150 may manipulate multiplexer 130 to couple each of the individual pads to voltage module 140 in a sequential fashion so that voltage module 140 may measure the voltage potential of each pad. Additionally, as voltage module 140 and multiplexer 130 measure the voltage potentials of each of the pads, processor 150 may store the magnitudes of the voltage potentials in memory 145. In doing so, processor 150 may create a voltage profile which corresponds or matches a pattern of the biometric component placed in the vicinity of the array of pads 125.

The types of memory devices of which memory 145 may comprise will vary in different embodiments. In some embodiments, memory 145 may comprise a volatile memory device, such as a random access memory (RAM) device. In other embodiments, memory 145 may comprise nonvolatile memory. For example in some embodiments memory 145 may comprise a flash memory module, such as a 1 gigabyte (GB) flash memory card. In such an embodiment, the flash memory card may have one or more biometric voltage profiles stored on it. When the card is removed from system 100, such voltage profiles may be stored in an alternate location and used to operate in another system, which may be similar to system 100.

Once processor 150 has created a voltage profile for the biometric component and stored the profile in memory 145, processor 150 may compare that voltage profile with other voltage profiles for other biometric components stored in a profile database 155. In other words profile database 155 may contain voltage profiles associated with the thumb prints of a group of authorized people, such as a group of people authorized to enter a building. In case processor 150 matches the recently created voltage profile in memory 145 with a stored profile in profile database 155, then processor 150 may grant access to a computing resource 165. For example, a person may want to gain access to a protected word processing document or login to a secure site on the Internet. The person may have system 100 scan their fingerprint using the array of pads 125. When processor 150 determines that the scanned voltage profile matches a profile in profile database 155, then processor 150 may allow the person to gain access to the protected word processing document or automatically log the person onto the Internet site.

In system 100, processor 150 may be coupled with a communication module 160. Communication module 160 may allow processor 150 to initiate and/or control external events upon a positive identification of a person. For example, once processor 150 determines that the scanned voltage profile of the fingerprint of a person matches a profile in profile database 155, processor 150 may activate or unlock a door and allow the person to enter a building. In other embodiments, communication module 160 may perform other functions such as presenting a message to a user via a display screen or transmitting the scanned voltage profile to an external device such as a flash memory device coupled with system 100. Additionally, communication module 160 may communicate with external devices in different ways. In some embodiments communication module 160 may communicate with external devices serially while in others it may communicate with them in parallel. As for serial communication example embodiments, communication module 160 may comprise a universal serial device (USB) device in one embodiment while comprising a FireWire® device in another embodiment. Additionally, communication module 160 may use a standard protocol in some embodiments while using a proprietary protocol in others. Even further, some embodiments may employ combinations of both serial and parallel communication, as well as both proprietary and open communication standards.

As mentioned, system 100 may take on various forms in various embodiments. In some embodiments, system 100 may comprise a laptop or notebook computer. In other embodiments, system 100 may comprise a security module in an automatic teller machine. And in further embodiments, system 100 may comprise a portable animal scanner used on a farm or in an office of a veterinarian. In even further embodiments, system 100 may comprise an integrated circuit in a stationary or mobile security apparatus.

While the embodiment of system 100 shown in FIG. 1 has processor 150, profile database 155, computing resource 165, and communication module 160, alternative embodiments may have different quantities of each element and may include other types of elements not shown. Many embodiments, for instance, may not restrict access to a computing resource. Some embodiments may include no communication module 160 whereby system 100 can communicate with external devices. For example, in a scenario where system 100 comprises a chip, system 100 may use a logical high signal at a single chip pin or signal line to indicate a positive match and a logical low signal to indicate an absence of a match. In other embodiments, system 100 may contain no profile database 155. In such an embodiment, system 100 may simply capture the voltage profile in memory 145 and transmit the profile information to an external system for match determination. On the other hand, system 100 may include other types of elements not shown. For instance, if system 100 comprises a notebook computer, then system 100 may have other types of elements, such as a keyboard, a hard drive, a display device, and numerous types of peripheral components.

System 100 may comprise hardware only elements in some embodiments while comprising hardware and software elements in others. In the embodiments comprising only hardware elements, system 100 may comprise a network of logic gates formed from constituent components such as complimentary metal oxide semiconductor (CMOS) devices or transistor-transistor logic (TTL) devices. In the embodiments comprising both hardware and software elements, elements such as source 120 and processor 150 may comprise CMOS or TTL devices. Additionally, these hardware devices may be arranged to execute software, firmware, or microcode program instructions residing in such devices as memory 145. For example, system 100 may comprise an industrial computing apparatus with a dual-core processor 150, 2 gigabytes (GB) of RAM for memory 145, and arranged to execute a UNIX® or Windows® XP operating system using processor 150.

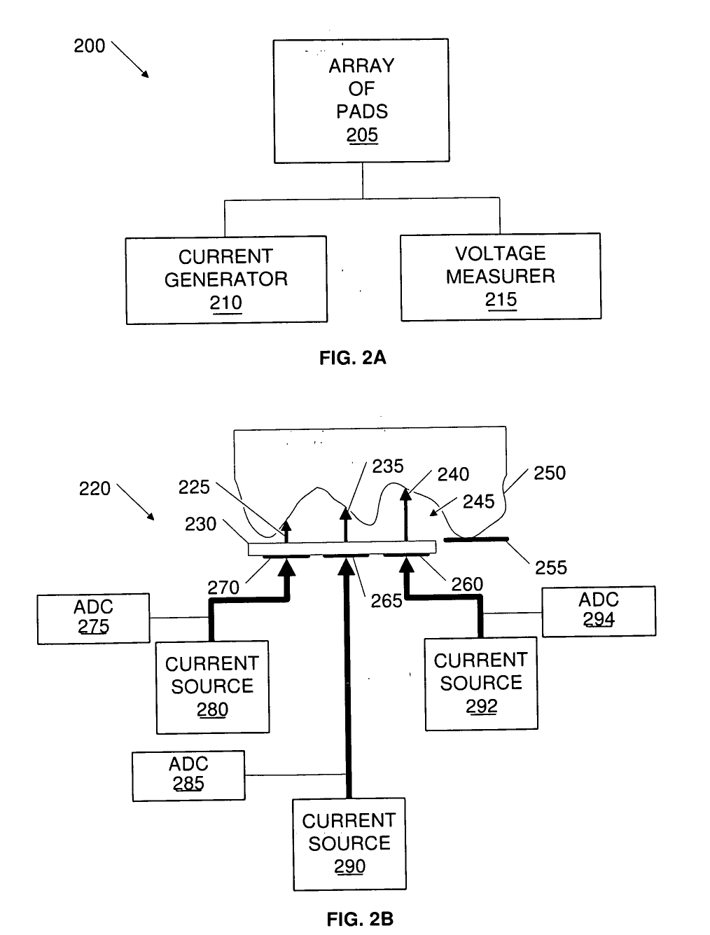

Moving now to FIG. 2A, we see an illustration of a sensor apparatus 200. Sensor apparatus 200 may be used to generate biometric profile information, such as voltage profiles or current profiles, for biometric components placed near or on an array of pads 205. The embodiment of sensor apparatus 200 depicted in FIG. 2A has a current generator 210 coupled to array of pads 205. Current generator 210 may generate quantum tunneling currents for the pads in array of pads 205. Once current generator 210 generates the quantum tunneling currents for array of pads 205, a voltage measurer 215 may measure voltage magnitudes of the pads in array of pads 205.

The number of current sources in current generator 210 of sensor apparatus 200 may vary in different embodiments. In some embodiments the number of current sources in current generator 210 may match the number of pads in array of pads 205. For example, if there are one thousand pads in array of pads 205 then there may be one thousand individual current sources in current generator 210. In alternative embodiments the number of current sources in current generator 210 may differ from the number of pads in array of pads 205. As examples, there may be one current source multiplexed amongst every one, two, or three pads in array of pads 205. In other embodiments there may only be one current source in current generator 210. In such a case, a current multiplexer may work in tandem with a voltage multiplexer either coupled with or contained in voltage measurer 215, sequentially selecting different individual pads in array of pads 205, generating a quantum tunneling current for each of the individual pads, and measuring the voltage magnitudes required to generate each of the tunneling currents via the voltage multiplexer coupled to voltage measurer 215.

As the number of current sources for current generator 210 may vary from embodiment to embodiment, so too may the numbers of voltage measurer 215. For example, one embodiment may employ one voltage measurer 215 for each pad in array of pads 205, which may eliminate the need for having any voltage multiplexer coupled with voltage measurer 215. Such an arrangement may be desirable when a rapid scan is desirable or necessary. Alternatively, some embodiments may have other combinational quantities of voltage multiplexers either coupled with or contained in voltage measurer 215. That is to say, an embodiment may have ten voltage measurers 215 coupled with ten voltage multiplexers, whereby each voltage measurer-multiplexer pair may measure the voltages of one hundred pads each when array of pads 205 contains one thousand pads.

To illustrate in more detail how an embodiment of a biometric sensor may generate tunneling currents and measure the voltage magnitudes required to generate the tunneling currents, we turn now to FIG. 2B. FIG. 2B shows a side view for an embodiment of a biometric sensor 220 having a first pad 270, a second pad 265, and a third pad 260. In an embodiment similar to the embodiment of biometric sensor 220 depicted in FIG. 2B, pads 270, 265, and 260 may be attached to a thin layer of insulating material 230. For example, insulating material 230 may comprise a thin layer of glass, such as a 0.050 millimeter (50 μm) thick layer of glass. Alternatively, insulating material 230 may comprise another material, such as plastic, polyester, a fabricated oxidation layer, passivation, or a transparent or opaque epoxy laminate. For example, insulating material 230 may comprise a thin film of Mylar® or Kapton®.

Biometric sensor 220 may be used to sense and record a unique biometric voltage profile for a biometric component 250. Biometric component 250 may comprise different biological parts of a human or other animal. For instance biometric component 250 may comprise the skin of a finger, a thumb, a toe, a portion of the palm, or a portion of a tongue, as examples. For an animal, biometric component 250 may comprise the flesh-padded digit of a dog or cat paw. Alternatively, biometric component 250 may comprise the skin on a nose of a cow or a pig. Even further, biometric component 250 may comprise a similar biological component of an undomesticated animal such as a cheetah, a panda bear, or a duck.

As illustrated in FIG. 2B when viewed up close, biometric component 250 may not be smooth but rather have a series of ridges and valleys. While the ridges, or peaks, of biometric component 250 may touch or come relatively close to insulating material 230 the valleys, or pockets, maybe positioned farther away. In the open spaces between biometric component 250 and insulating material 230 there may be a dielectric medium 245. In many embodiments dielectric medium 245 may comprise air. In some embodiments, however, dielectric medium 245 may comprise another material or gas, such as saliva, water, or a type of oil.

Once biometric component 250 is placed on or substantially close to insulating material 230, current sources 280, 290, and 292 may create quantum tunneling currents 225, 235, and 240, respectively. More specifically, current source 280 may create a voltage potential at pad 270 which causes quantum tunneling current 225 to flow from the outer surface of insulating material 230 to the surface of biometric component 250. Similarly, current sources 290 and 292 may create voltage potentials at pads 265 and 260 which cause quantum tunneling currents 235 and 240 to flow from the outer surface of insulating material 230 to the surface of biometric component 250.

Since the distances from insulating material 230 to the ridges of biometric component 250 are different from the distances to the valleys, the magnitudes of the voltage potentials of pads 270, 265, and 260 may be correspondingly different as well. In other words, since a ridge of biometric element 250 is relatively close to insulating material 230 and pad 270, the amount of voltage required to generate quantum tunneling current 225 may be relatively small. On the other hand, since the distance from pad 260 and insulating material 230 to the valley of biometric component 250 is relatively far away, as compared to the distance for pad 270, the amount of voltage required to generate quantum tunneling current 240 at pad 260 may be appreciably larger than the voltage present at pad 270. Stated differently, larger distances between the surface of biometric component 250 and insulating material 230 may require higher voltages to generate tunneling currents than those pads closer to the surface of biometric component 250.

The magnitudes of the voltages required to create the quantum tunneling currents at the individual pads may vary significantly depending on embodiment specifications, dielectric medium 245, and the electrical characteristics of biometric component 250. For example, when insulating material 230 has an average thickness of 250 micrometers, the magnitude of the pad voltage required to generate a tunneling current for a given distance to biometric component 250 may be 11 volts DC, while the voltage may jump to 16 volts DC when the average thickness of insulating material 230 is increased to 360 micrometers, assuming the distance to biometric component 250 is the same. Similarly, dielectric mediums 245 having relatively high dielectric strengths may require relatively large voltage magnitudes to generate the quantum tunneling currents, while dielectric mediums 245 having relatively low dielectric strengths may require lower voltage magnitudes.

As mentioned, the electrical characteristics of biometric component 250 may also affect the voltage magnitudes required to generate quantum tunneling currents 225, 235, and 240. When the surface of biometric component 250 is smooth, quantum tunneling currents may be generated at pads 270, 265, and 260 with relatively low average pad voltage magnitudes, while rough surfaces of biometric component 250 may require higher average pad voltages. In other words, deeper valleys may increase the overall average voltage magnitudes required to create quantum tunneling currents. Additionally, the size and electrical properties of biometric component 250 may affect the magnitudes of voltages. When biometric component 250 comprises a thumb, the overall biometric surface area and volume may be relatively small. Accordingly, the overall resistance encountered by the quantum tunneling currents may be relatively low since resistance may be a function of both cross sectional area and length. For example, many embodiments may have a ground element 255 situated in close proximity to pads 270, 265, and 260 in order to provide a current return path so that the quantum tunneling currents may flow back to current source 280, current source 290, and current source 292. When the size, or more specifically the length in this case, between a pad and ground element 255 is relatively short, the magnitude of the voltage required to generate the quantum tunneling currents will be relatively low when compared to embodiments where the distance between the pad and the ground element is relatively long. For example, the voltage magnitudes required to generate quantum tunneling currents at pads located the farthest away from ground element 255 may be larger for an embodiment senses a palm of a human and smaller for the farthest pads when biometric sensor 220 senses a thumb, since the distance between the farthest pad and ground element 255 may be shorter when sensing the thumb. By reasoning, then, when biometric component 250 has a low per-unit resistance, lower voltage magnitudes may be required to generate the tunneling currents than when biometric component 250 has a high per-unit resistance.

As the magnitudes of the voltages may vary in different embodiments and under different conditions, so too may the magnitudes of the currents. For example, in those scenarios where the resistance of biometric component 250 is high, the dielectric strength of dielectric medium 245 is high, and/or the thickness of insulating material 230 is large, the corresponding voltage magnitudes required to generate the quantum tunneling currents may be relatively large. Conversely, for those scenarios where the resistance of biometric component 250 is low, the dielectric strength of dielectric medium 245 is low, and/or the thickness of insulating material 230 is small, the corresponding voltage magnitudes required to generate the quantum tunneling currents may be relatively small.

The magnitudes of the quantum tunneling currents may also vary in different embodiments depending on how current sources 280, 290, and 292 are controlled. In some embodiments, current source 292 may be operated so that it causes a 20 nanoampere quantum tunneling current 240 to flow from pad 260, through insulating material 230, through dielectric medium 245, through biometric component 250, and to ground element 255. Alternatively, in other embodiments, current source 292 may be operated so that it generates a 180 nanoampere quantum tunneling current 240.

Once current sources 280, 290, and 292 generate quantum tunneling currents 225, 235, and 240, respectively, then the voltage magnitudes of pads 270, 265, and 260 may be measured to determine a voltage profile for biometric component 250. Described in more detail, analog-to-digital converter 275 may measure the voltage magnitude for pad 270, while analog-to-digital converter 285 may measure the voltage magnitude for pad 265 and analog-to-digital converter 294 may measure the voltage magnitude for pad 260. As an example for the embodiment of FIG. 2B, one voltage profile sampled and measured by biometric sensor 220 may consist of pad 270 having a voltage magnitude of 12.6 volts DC, pad 265 having a voltage magnitude of 14.2 volts DC, and pad 260 having a voltage magnitude of 18.9 volts DC. Whenever biometric 250 is placed over insulating material 230 and pads 270, 265, and 260 in the same or substantially the same location, then the re-sampled voltage profile should again be approximately 12.6 volts DC, 14.2 volts DC, and 18.9 volts DC for pads 270, 265, and 260, respectively. A comparison of a current scan profile of biometric component 250 and a saved profile of biometric component 250, then, should result in a positive match.

As conditions change, the voltage profiles measured by biometric sensor 220 for the same biometric component 250 may vary. For example, insulating material 230 may wear thin with use and/or accumulate a film of dust or dirt. Additionally, environmental conditions may change the properties of both dielectric medium 245 and biometric component 250. Heat and humidity may affect the dielectric properties of dielectric medium 245, such as making it denser with cool temperatures and increasing its dielectric strength or increasing the humidity and which may increase the dielectric strength. Under such conditions, the voltage profile for biometric component 250 may shift up or down. For example, the profile may be 12.6, 14.2, and 18.9 volts under one set of conditions, yet be 12.9, 14.6, and 19.4 volts under a second set of conditions, such as when insulating material 230 is dirty. A computer or processor may execute a program or sequence of instructions that compensate for such variations and changes in environmental conditions, yet still indicate a positive match for the same biometric component 250.

Hot and cold temperatures may also affect the properties of biometric component 250. Hot temperatures may cause biometric component 250 to expand and increase its internal resistance. Cool temperatures may cause biometric component 250 to contract and decrease internal resistance. Aside from changes in electrical properties of biometric component 250, physical changes may result from changes in temperature. Hot temperatures may cause the surface area of biometric component 250 to increase while cooler temperatures may cause the surface area to decrease. Similar to the way a program or sequence of instructions may accommodate variations in the magnitudes of the voltage profile readings due to changes in layer insulating material 230 and dielectric medium 245, a program or sequence of instructions may also be able to accommodate changes in biometric component 250. For example, as a higher or hotter temperature may increase the size or cross sectional area of biometric component 250, the associated pattern or voltage profile measured by biometric sensor 220 may be skewed. In other words, the peaks and valleys of biometric component 250 may shift to different areas of biometric sensor 220 during a scan, causing biometric sensor 220 to detect a different pattern, or voltage profile. A program may detect this skew and either adjust the voltage profile or compensate in a different manner accordingly, when attempting to decide if the voltage profile matches a stored profile.

To provide the resolution and accuracy necessary to sample, detect, and adjust voltage profiles for the patterns of different biometric components 250, the individual devices making up biometric sensor 220 may be fabricated from a variety of electrical devices. For example, current source 292 and analog-to-digital converter 275, as well as the other current sources and voltage measurement elements of biometric sensor 220, may be fabricated using CMOS elements. In using CMOS elements, the individual devices may be able to control the magnitudes of both the quantum tunneling currents and the corresponding voltage potentials of the pads in a precise manner. Additionally, the measuring elements may be able to measure the voltages necessary to create quantum tunneling to a very precise degree. For example, analog-to-digital converters 285, 292, and 275 may all comprise eight, twelve, or fifteen bit converters, as examples. Similarly, current sources 280, 290, and 292 may be fabricated so that they regulate the quantum tunneling currents between, for example, 98.5 nanoamperes and 106.2 nanoamperes, with corresponding pad voltages of 6.8459012 and 6.8468721 volts DC.

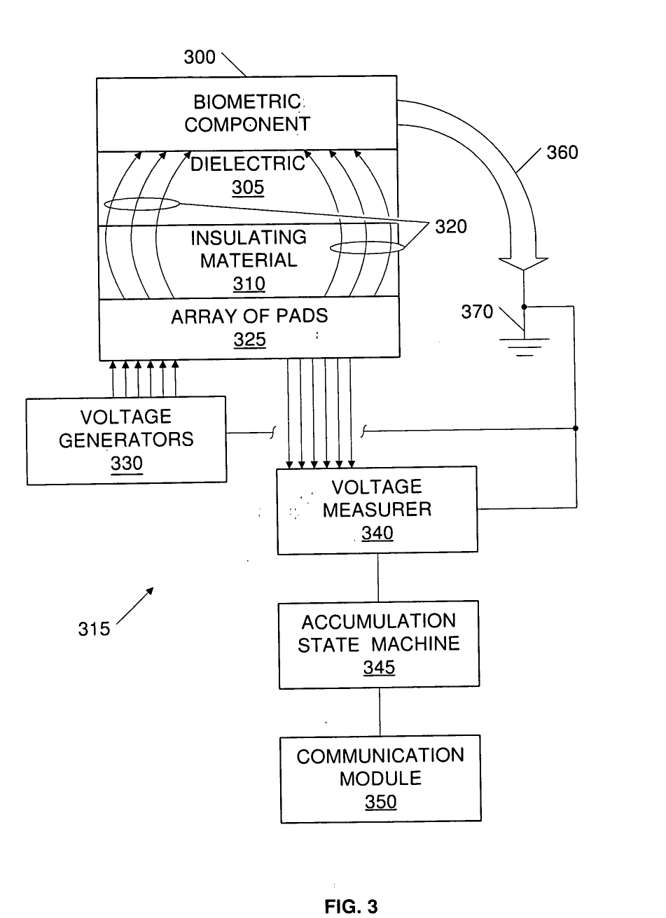

To more clearly illustrate the circuit paths where quantum tunneling currents may flow and how such currents may be regulated or controlled, we move now to FIG. 3. FIG. 3 depicts an alternative embodiment of a biometric apparatus 315. Similar to several of the other embodiments described heretofore, biometric apparatus 315 has an array of pads 325 that may be used to generate numerous quantum tunneling currents 320 via a group of voltage generators 330. Similar to current sources 280, 290, and 292 shown in FIG. 2B, the group of voltage generators 330 may generate sufficient pad voltages for the pads in array of pads 325 to create quantum tunneling currents 320. However, the group of voltage generators 330 may monitor and throttle the individual pad voltages, once quantum tunneling current flow is established. For example, in some embodiments current monitoring circuits may monitor the currents flowing from the individual pads. Once quantum tunneling currents are initiated from individual pads, the current monitoring for those pads may cease and the group of voltage generators 330 may start monitoring and controlling only the pad voltages. Once quantum tunneling has been established for all of the pads in array of pads 325, the group of voltage generators 330 may only be controlling voltage directly and the respective quantum tunneling currents 320 indirectly.

Once the quantum tunneling currents 320 are established, they may flow through insulating material 310 and dielectric medium 305 to biometric component 300. Upon reaching biometric component 300, the quantum tunneling currents 320 may flow in a common current return path 360 back to a ground element 370. In some embodiments ground element 370 may comprise a dedicated conductive ring placed around array of pads 325, such that when biometric component 300 is placed near array of pads 325 it will likely contact ground element 370. In some alternative embodiments ground element 370 may actually comprise numerous contact points strategically located among the pads in array of pads 325.

The magnitudes of the voltages applied to the pads in array of pads 325 may be measured or sampled via voltage measurer 340. Once voltage measurer 340 samples the pad voltages of array of pads 325 and creates a voltage profile corresponding to the particular biometric component 300 being examined, the associated values of the voltage profiles may be stored in a memory device via an accumulation state machine 345. For example, accumulation state machine 345 may facilitate the collection and reading out of the values in analog-to-digital data arrays within voltage measurer 340.

Communication module 350 may take the voltage profile values accumulated with accumulation state machine 345 and transfer them to another apparatus coupled with biometric apparatus 315. For example, communication module 350 may transfer the voltage profile values to an application specific integrated circuit (ASIC) coupled to biometric apparatus 315. The ASIC may in turn manipulate or adjust the voltage profile values and compare the adjusted voltage profile values with previously stored voltage profiles to find a matching stored profile.

Worth emphasizing is how quantum tunneling currents 320 may be first generated and then be controlled once established. As mentioned above, an embodiment similar to the embodiment of biometric apparatus 315 depicted in FIG. 3 may generate quantum tunneling currents 320 via the group of voltage generators 330. However, in alternative embodiments the group of voltage generators 330 may be replaced with a group or array of current generators or sources, similar to the array of current sources 105 shown in FIG. 1. Both the group of voltage generators 330 and the array of current sources may generate the quantum tunneling currents by varying the voltages applied to pads in array of pads 325.

In some embodiments, the individual pad voltages may be increased until individual quantum tunneling currents are established. Upon establishing either minimum or fixed magnitude currents, the voltages may then be held constant until they are measured via voltage measurer 340. However, in alternative embodiments, the pad voltages may instead be rapidly ramped up until individual quantum tunneling currents are established. In this scenario, a voltage may overshoot the minimum voltage necessary for quantum tunneling current flow. Accordingly, the pad voltage may be monitored and throttled back or controlled to regulate a minimum quantum tunneling current flow. In other words, the voltages of the pads may still be DC voltages but they may fluctuate and change when being controlled by the group of voltage generators 330 or an array of current sources.

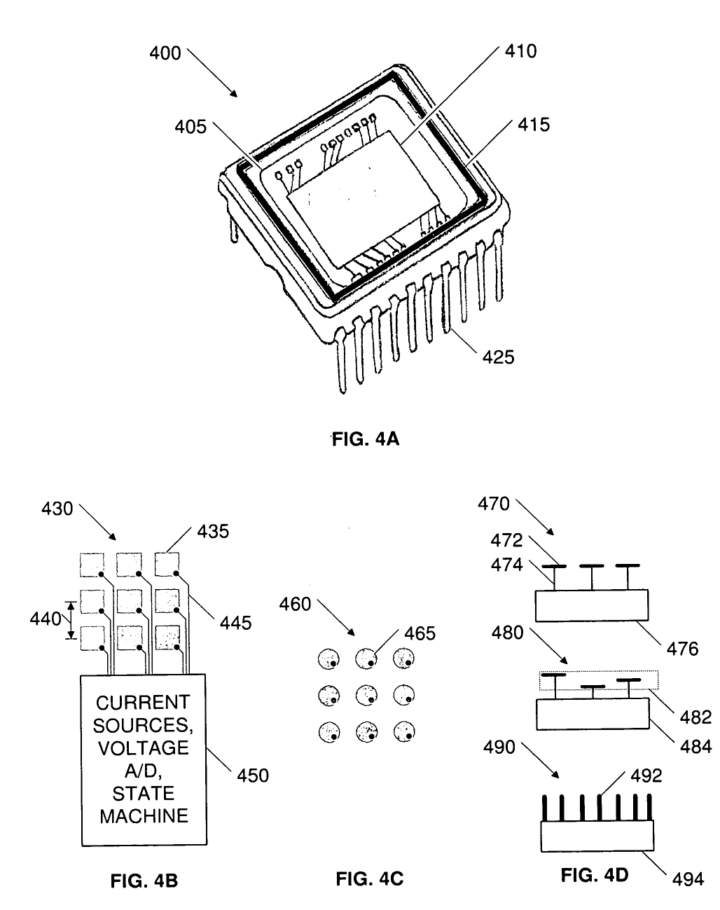

FIG. 4A depicts one embodiment of a biometric sensor 400 implemented in the form of a circuit board chip. For example, biometric sensor 400 may be mass manufactured in chip form and sold to systems integrators so that they may utilize biometric scanning in their respective hardware platforms. Biometric sensor 400 may have numerous circuit board insertion pins, such as pin 425 for coupling biometric sensor 400 with a circuit board and other elements in the system employing biometric sensor 400.

In some embodiments biometric sensor 400 may comprise an array of pads 410 along with one or more current sources, one or more voltage modules, a processor, and memory. In other words, biometric sensor 400 may have sufficient electronics to perform a scan and a voltage profile comparison in the chip. In other embodiments, biometric sensor 400 may lack such elements as the processor and memory. In these embodiments, a processor or hardware state machine performing similar functions may need to be coupled with biometric sensor 400 in order to scan a biometric component and find a corresponding matching voltage profile.

Biometric sensor 400 may have an insulating material 405, such as glass, used to protect array of pads 410. Additionally, biometric sensor 400 may have a ground element 415 that runs around the periphery of the face of biometric sensor 400. As illustrated in FIG. 4A, ground element 415 may be on the surface of biometric sensor 400 and encircle insulating material 405. Arranged in this fashion, ground element 415 may easily contact with a biometric component placed on biometric sensor 400 during a profile scan.

FIG. 4B illustrates one implementation of an array of pads 430. As illustrated, array of pads 430 may comprise a number of pads, such as pad 435, arranged in a grid-like fashion. Each pad in array of pads 430 may have an individual conductor coupling it with other sensor electronics 450. For example, pad 435 has a conductor 445 coupling it to sensor electronics 450. For the sake of simplicity and for the purpose of illustration, array of pads 430 only contains nine pads. However, embodiments may contain tens, hundreds, and thousands of such pads. When arranged in a grid as shown in FIG. 4B, the individual pads may be spaced relatively close together and have various distances of pitch 440. For example, an embodiment may create or fabricate array of pads 430 in a fairly large die. Each of the individual pads, such as pad 435, may have an approximate surface area of ten square micrometers. In such a case, pitch 440 may measure approximately 40 micrometers and provide a corresponding sensor resolution of approximately 500 dots per inch.

FIG. 4C illustrates how alternative embodiments may have different shapes for the individual pads. As shown in FIG. 4C, array of pads 460 has circular-shaped pads such as pad 465. Other embodiments may have other shaped pads. As illustrative examples, pad 465 may be shaped in the form of an oval, a hexagon, an octagon, or an elongated diamond.

FIG. 4D illustrates various implementations of pad arrays. Array of pads 470 illustrates what may be the side view of an array of pads similar to array of pads 430 or array of pads 460 in FIGS. 4B and 4C, respectively. For example, pad 472 may have conductor 474 coupling pad 472 to a base substrate structure 476, wherein pad 472 and conductor 474 may correspond to pad 435 and conductor 445 shown in FIG. 4B. As depicted the pads in array of pads 470 may lie precisely in a relatively narrow plane. In alternative embodiments, however, the pads may reside at different distances from substrate structure 476. For example, the pads in array of pads 480 may reside at different heights relative to substrate structure 484. Even so, the pads in array of pads 480 may still substantially reside in plane 482, albeit more broad than the plane containing array of pads 470. Arranging pads in array of pads 480 at different heights may allow a manufacturer to create a biometric sensor having a curved surface which may more easily accommodate or follow the natural contour of a fingertip. Such an embodiment may allow a sensor to develop a larger voltage profile via more pads, resulting in improved profile recognition accuracy.

FIG. 4D also illustrates an array of pads 490, wherein each of the pads have relatively small pad surface areas. As shown, a pad may comprise merely the upper surface area of an individual conductor, such as conductor 492 extended up from substrate base 494. Minimizing the surface area of individual pads in this manner may allow greater numbers of pads to be crammed into smaller per unit areas. Such a practice may be desired, for example, when extremely high sensor resolution is needed or desired.

Each of the pads in array of pads 430, 460, 470, 480, and 490 may comprise the top metal layer of a particular silicon fabrication process. These pads may comprise the metal, or contacts, of the top layer metal feature in an inner part of a die, and have a layer of passivation, or oxide, or other evenly deposited substantially non-conductive material coating the metal for protection and insulation.

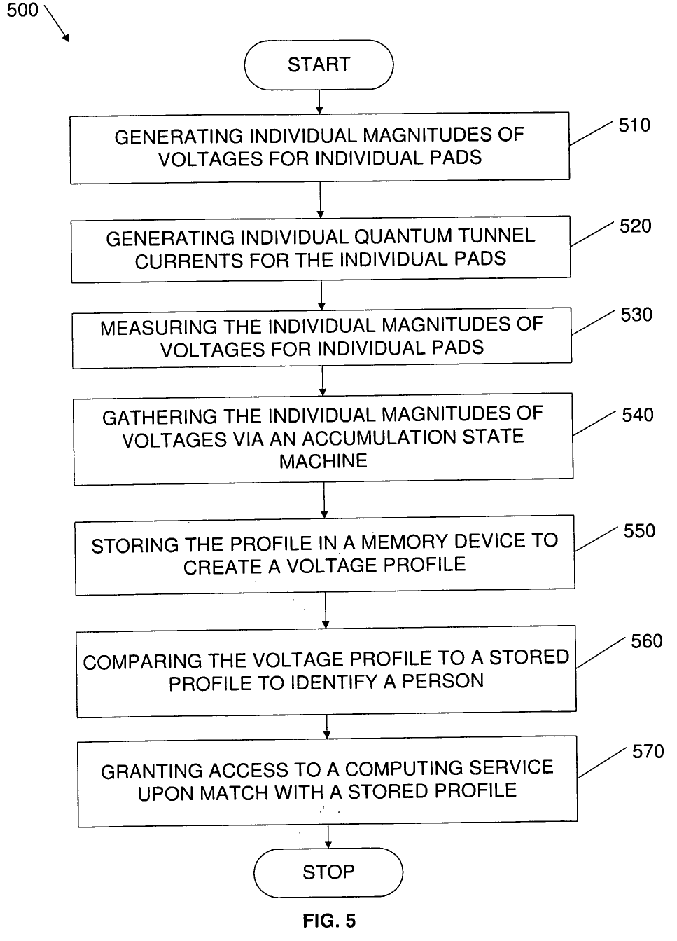

FIG. 5 depicts a flowchart 500 illustrating an embodiment of a method for identifying an individual and granting access to a computing service, based upon biometric information obtained from quantum tunneling currents. Flowchart 500 begins with generating individual magnitudes of voltages for individual pads (element 510). For example, current or voltage sources may generate individual pad voltages in an array of pads similar to array of pads 125 shown in FIG. 1. Upon generating the individual magnitudes of voltages (element 510), an embodiment according to flowchart 500 may continue by generating individual quantum tunneling currents for the individual pads (element 520). For example, generating the individual quantum tunneling currents may involve throttling the individual current or voltage sources so that a minimum tunneling current is established for each pad.

The method embodiment of flowchart 500 may continue by measuring the individual magnitudes of voltages for the individual pads (element 530) and storing the individual magnitudes of voltages in a memory device to create a voltage profile (element 550) by using an accumulation state machine (element 540). In alternative method, apparatus, and system embodiments, quantum tunneling current profiles may be created instead of voltage profiles. For example, an embodiment may involve holding all of the pads in an array of pads at a constant voltage, such as 18.005 volts. Once the voltages for each of the individual pads is established, a current measuring module may measure the magnitudes of each of the currents flowing from the individual pads, and capture them using an accumulation state machine and memory in order to create a quantum tunneling current profiles for various biometric components.

In alternative embodiments, a method embodiment may involve capturing a series of voltage profiles during a scan and consolidating the voltage profiles into a comprehensive biometric voltage profile. For example, a biometric scanner may sample five voltage profiles during a 0.25 second scanning window, as a person drags his or her finger or thumb across the biometric scanner. Such a technique may allow for more accurate voltage profiles, resulting in greater recognition accuracy, or the technique may allow a biometric scanner which is smaller than the biometric component to sample the larger surface area of the biometric component. In other words, the biometric scanner may capture five different partial “snapshot” profiles and concatenate them to create a full voltage profile.

The method embodiment according to flowchart 500 may proceed by comparing the voltage profile in the memory device to a stored profile, so that a person may be identified (element 560). If a positive match is made, then a method according to flowchart 500 may continue by granting access to a computing service, or resource, upon the successful match (element 570). For example, the person may be allowed to login to a notebook operating system or logon to a secure website.

Another embodiment of the invention is implemented as a program product for use with a biometric sensor apparatus to identify a person or an animal, such as the processes described in identifying people or animals with system 100 as illustrated in FIG. 1. The program(s) of the program product defines functions of the embodiments (including the methods described herein) and can be contained on a variety of data and/or signal-bearing media. Illustrative data and/or signal-bearing media include, but are not limited to: (i) information permanently stored on non-writable storage media (e.g., read-only memory devices within a computer such as CD-ROM disks readable by a CD-ROM drive); (ii) alterable information stored on writable storage media (e.g., floppy disks within a diskette drive or hard-disk drive); and (iii) information conveyed to a computer by a communications medium, such as through a computer or telephone network, including wireless communications. The latter embodiment specifically includes information downloaded from the Internet and other networks. Such data and/or signal-bearing media, when carrying computer-readable instructions that direct the functions of the present invention, represent embodiments of the present invention.

In general, the routines executed to implement the embodiments of the invention, may be part of an operating system or a specific application, component, program, module, object, or sequence of instructions. The computer program of the present invention typically is comprised of a multitude of instructions that will be translated by a computer into a machine-readable format and hence executable instructions. Also, programs are comprised of variables and data structures that either reside locally to the program or are found in memory or on storage devices. In addition, various programs described hereinafter may be identified based upon the application for which they are implemented in a specific embodiment of the invention. However, it should be appreciated that any particular program nomenclature that follows is used merely for convenience, and thus the invention should not be limited to use solely in any specific application identified and/or implied by such nomenclature.

It will be apparent to those skilled in the art having the benefit of this disclosure that the present invention contemplates methods, apparatuses, systems, and media to identify persons and things using quantum tunneling. It is understood that the form of the invention shown and described in the detailed description and the drawings are to be taken merely as examples. It is intended that the following claims be interpreted broadly to embrace all the variations of the embodiments disclosed.

Although the present invention and some of its aspects have been described in detail for some embodiments, it should be understood that various changes, substitutions and alterations can be made herein without departing from the spirit and scope of the invention as defined by the appended claims. Although an embodiment of the invention may achieve multiple objectives, not every embodiment falling within the scope of the attached claims will achieve every objective. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

1. An apparatus for biometric identification comprising:
an array of pads;
a first number of current generators to generate quantum tunneling currents to flow from a number of pads in the array through a dielectric medium, wherein the quantum tunneling currents are to flow to a biometric element; and
at least one voltage measurer to measure voltage magnitudes of the number of pads.

2. The apparatus of claim 1, further comprising a ground element coupled to the first number of current generators, wherein the ground element is to provide a return path for the quantum tunneling currents.

3. The apparatus of claim 1, further comprising a layer of insulating material coupled to the array of pads.

4. The apparatus of claim 3, wherein the layer of insulating material comprises one of glass, oxide, passivation, or plastic.

5. The apparatus of claim 1, further comprising an accumulation state machine coupled to the at least one voltage measurer to collect measurements of the voltage magnitudes.

6. The apparatus of claim 1, further comprising a multiplexer coupled to the at least one voltage measurer, the multiplexer to couple the at least one voltage measurer with the number of pads.

7. The apparatus of claim 6, further comprising a communication module to transfer measurements of the voltage magnitudes to an external circuit coupled to the biometric sensor apparatus.

8. The apparatus of claim 1, wherein the array of pads are substantially arranged in a plane.

9. (canceled)

10. The apparatus of claim 1, wherein the biometric component comprises an arrangement of ridges of a human hand.

11. The apparatus of claim 1, wherein the quantum tunneling currents are direct current quantum tunneling currents.

12. The apparatus of claim 1, wherein the first number of current generators equals the number of pads.

13. A method of biometric identification, the method comprising:
generating individual magnitudes of voltages for individual pads in an array of pads;
generating individual quantum tunnel currents for the individual pads via the individual magnitudes of voltages, wherein the individual quantum tunnel currents flow between the individual pads and a biometric component through a dielectric medium; and
measuring the individual magnitudes of voltages to create a voltage profile of the biometric component.

14. The method of claim 13, further comprising storing the individual magnitudes of via an accumulation state machine.

15. The method of claim 13, further comprising storing the individual magnitudes of voltages in a memory device.

16. The method of claim 15, further comprising retrieving the individual magnitudes via a communication module.

17. The method of claim 13, further comprising comparing the voltage profile with a second voltage profile to identify a person of the biometric component.

18. The method of claim 17, further comprising granting access to a computing service when the voltage profile substantially matches the second voltage profile.

19. The method of claim 13, further comprising moving the biometric component relative to the array of pads to generate more than one voltage profile.

20. The method of claim 13, wherein generating the individual magnitudes of voltages for the individual pads comprises varying the individual magnitudes of voltages to generate the individual quantum tunnel currents.

21. A system for biometric identification, the system comprising:
an array of current sources to generate quantum tunneling currents to flow through a dielectric medium, from an array of pads, to a biometric element coupled to the system via the quantum tunneling currents;
a voltage module to measure magnitudes of voltages of the array of pads;
at least one power supply coupled to the array of current sources; and
a DRAM module coupled to the voltage module.

22. The system of claim 21, further comprising an insulating material coupled to the array of pads.

23. The system of claim 21, further comprising a ground element coupled to the array of current sources to provide a return path for the quantum tunneling currents.

24. The system of claim 21, further comprising a memory device coupled to the voltage module to store the magnitudes of voltages.

25. The system of claim 24, further comprising a processor to compare the magnitudes of voltages with stored magnitudes of voltages to identify the animal.

26. The system of claim 21, wherein the voltage module comprises an analog-to-digital converter.

27. The system of claim 21, wherein the dielectric medium comprises air.

28. A machine-accessible medium containing instructions, which when executed by an apparatus, cause the apparatus to perform operations, the operations comprising:
generating individual magnitudes of voltages for individual pads in an array of pads;
generating individual quantum tunnel currents for the individual pads via the individual magnitudes of voltages, wherein the individual quantum tunnel currents flow between the individual pads and a biometric component through a dielectric medium; and
measuring the individual magnitudes of voltages to create a voltage profile of the biometric component.

29. The method of claim 28, further comprising comparing the voltage profile with a second voltage profile to identify a person of the biometric component.

30. The method of claim 29, further comprising granting access to a computing service when the voltage profile substantially matches the second voltage profile.
